(19) United States
(12) Patent Application Publication
(10) Pub. No.: US 2024/0203904 A1
(43) Pub. Date: Jun. 20, 2024

(54) STRESS MODULATING PATTERN CONTAINING BONDING DIELECTRIC LAYER

(71) Applicant: International Business Machines Corporation, Armonk, NY (US)

(72) Inventors: FEE LI LIE, Albany, NY (US); Hosadurga Shobha, Niskayuna, NY (US); Michael Rizzolo, Delmar, NY (US); Aakrati Jain, Albany, NY (US); Sagarika Mukesh, ALBANY, NY (US); Christopher J. Waskiewicz, Rexford, NY (US)

(21) Appl. No.: 18/083,994

(22) Filed: Dec. 19, 2022

(51) Int. Cl. H01L 23/00

(52) U.S. Cl. CPC H01L 23/562; H01L 23/5226

(57) ABSTRACT

A semiconductor structure is provided that includes a stress modulating pattern containing bonding dielectric layer. The stress modulating pattern containing bonding dielectric layer can be formed on a wafer, on a device-containing region that is present on a device wafer, or both a wafer and a device-containing region that is present on a device wafer. The stress modulating pattern is composed of a plurality of patterned structures (metal and/or dielectric) that are embedded at least partially within a bonding dielectric layer. Warpage modulation can be achieved using such a stress modulating pattern containing bonding dielectric layer.

### BACKGROUND

The present application relates to semiconductor technology, and more particularly to a semiconductor structure that enables warpage modulation of a device wafer, without impacting the ability to process the device wafer in downstream processing tools.

Pattern distortion in a device wafer during bonding can lead to warpage and alignment/overlay issues for the next level build-up from the backside of the device wafer. Single warpage modulation by backside patterning has been suggested; however, patterns on the backside could cause potential issues in the downstream processing tools.

### SUMMARY

A semiconductor structure is provided that includes a stress modulating pattern containing bonding dielectric layer. The stress modulating pattern containing bonding dielectric layer can be formed on a wafer, on a device-containing region that is present on a device wafer, or both a wafer and a device-containing region that is present on a device wafer. The stress modulating pattern is composed of a plurality of patterned structures (metal and/or dielectric) that are embedded at least partially within a bonding dielectric layer. Warpage modulation can be achieved using such a stress modulating pattern containing bonding dielectric layer.

In one aspect of the present application, a semiconductor structure is provided. In one embodiment of the present application, the semiconductor structure includes a first bonding dielectric layer located on a surface of a wafer, a second bonding dielectric layer located on the first bonding dielectric layer, a device-containing region located on the second bonding dielectric layer, and a device wafer located on the device-containing region. In accordance with the present application, at least one of the first bonding dielectric layer or the second bonding dielectric layer is a stress modulating pattern containing bonding dielectric layer including a plurality of patterned structures.

In embodiments of the present application, only the first bonding dielectric layer is the stress modulating pattern containing bonding dielectric layer. In such embodiments, the patterned structures can be embedded entirely in the first bonding dielectric layer, or embedded partially in both the first bonding dielectric layer and the wafer.

In embodiments of the present application, only the first bonding dielectric layer is the stress modulating pattern containing bonding dielectric layer. In such embodiments, the patterned structure is at least partially embedded in the second bonding dielectric layer and contacts (either directly or indirectly) the device-containing region.

In embodiments of the present application, both the first bonding dielectric layer and the second bonding dielectric layer are stress modulating pattern containing bonding dielectric layers.

In another aspect, a microelectronic assembly is provided that includes a first bonding dielectric layer located on a surface of a die; a second bonding dielectric layer located on the first bonding dielectric layer; a device-containing region located on the second bonding dielectric layer; and a device die located on the device-containing region, wherein at least one of the first bonding dielectric layer or the second bonding dielectric layer is a stress modulating pattern containing bonding dielectric layer comprising a plurality of patterned structures.

### BRIEF DESCRIPTION OF THE DRAWINGS

FIG. 1A is a cross sectional view of an exemplary structure that can be employed in accordance with a first embodiment of the present application, the exemplary structure includes a first bonding dielectric layer located on a wafer, wherein the first bonding dielectric layer contains a plurality of patterned structures which are entirely embedded in the first bonding dielectric layer and formed on a surface of the wafer.

FIG. 1B is a cross sectional view of an exemplary structure that can be employed in accordance with a second embodiment of the present application, the exemplary structure includes a first bonding dielectric layer located on a wafer, wherein the first bonding dielectric layer contains a plurality of patterned structures which are partially embedded in both the first bonding dielectric layer and the wafer.

FIGS. 1C and 1D illustrate various grids in which the stress modulating pattern can be arranged on a wafer level scale in the present application.

FIG. 2 is a cross sectional view of a device containing structure that can be employed in the present application, the device containing structure includes a device-containing region located on a second bonding dielectric layer, and a device wafer located on the device-containing region and physically exposed portions of the second bonding dielectric layer not including the device-containing region.

FIG. 3A is a cross sectional view of an exemplary structure that is formed after bonding the first bonding dielectric layer of the exemplary structure shown in FIG. 1A to the second bonding dielectric layer of the device containing structure shown in FIG. 2.

FIG. 3B is a cross sectional view of an exemplary structure that is formed after bonding the first bonding dielectric layer of the exemplary structure shown in FIG. 1B to the second bonding dielectric layer of the device containing structure shown in FIG. 2.

FIG. 4A is a cross sectional view of the exemplary structure shown in FIG. 3A after thinning the device wafer to physically expose the device-containing region.

FIG. 4B is a cross sectional view of the exemplary structure shown in FIG. 3B after thinning the device wafer to physically expose the device-containing region.

FIG. 5A is a cross sectional view of the exemplary structure shown in FIG. 4A after backside processing, the backside processing including forming a backside interlayer dielectric material layer having wiring and/or contact structures embedded therein.

FIG. 5B is a cross sectional view of the exemplary structure shown in FIG. 4B after backside processing, the backside processing including forming a backside interlayer dielectric material layer having wiring and/or contact structures embedded therein.

FIG. 6A is a cross sectional view of the exemplary structure shown in FIG. 5A post solder bump formation.

FIG. 6B is a cross sectional view of the exemplary structure shown in FIG. 5B post solder bump formation.

FIG. 7A is a cross sectional view of an exemplary structure that can be employed in accordance with a third embodiment of the present application, the exemplary structure includes a second bonding dielectric layer located on a device-containing region that is located on a device wafer, wherein the second bonding dielectric layer contains a plurality of patterned structures which are entirely embedded in the second bonding dielectric layer and formed on the device-containing region.

FIG. 7B is a cross sectional view of the exemplary structure shown in FIG. 7A after bonding the second bonding dielectric layer to the first bonding dielectric layer shown in FIG. 1A.

FIG. 7C is a cross sectional view of the exemplary structure shown in FIG. 7A after bonding the second bonding dielectric layer to a first bonding dielectric layer that is located on a wafer; in this example, the first bonding dielectric layer does not include a plurality of patterned structures embedded therein.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

A semiconductor structure that enables warpage modulation of a device wafer, without impacting the ability to process the device wafer in downstream processing tools, is provided. The semiconductor structure includes a stress modulating pattern containing bonding dielectric layer. The stress modulating pattern containing bonding dielectric layer can be formed on a wafer, on a device-containing region that is present on a device wafer, or both a wafer and a device-containing region that is present on a device wafer. The stress modulating pattern is composed of a plurality of patterned structures (metal and/or dielectric) that are at least partially embedded in the bonding dielectric layer. The patterned structures are arranged in patterns that counter wafer warpage that can occur. In the present application, the stress modulating pattern containing bonding dielectric layer is formed prior to processing the backside of the device wafer.

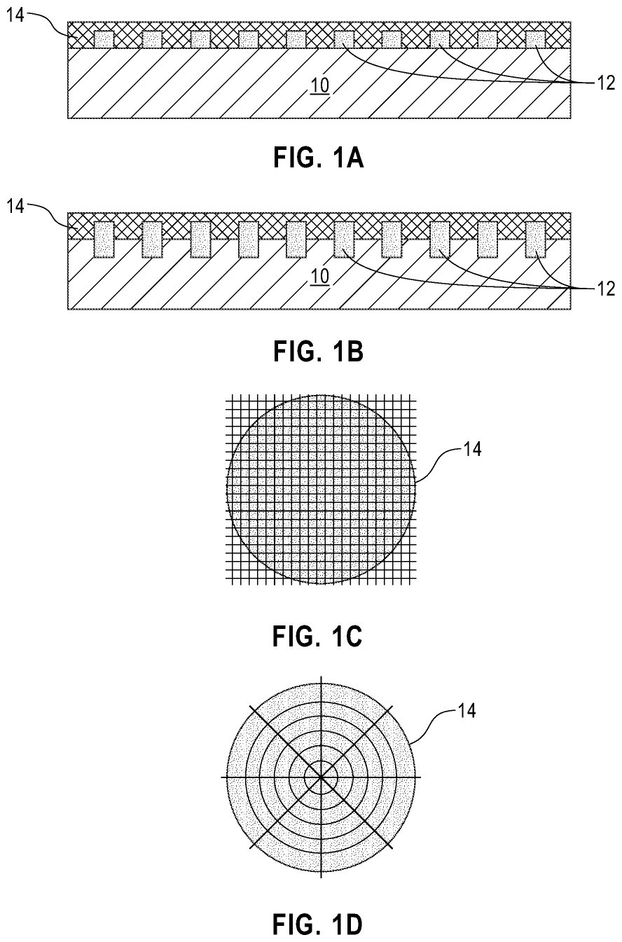

Referring first to FIG. 1A, there is illustrated an exemplary structure that can be employed in accordance with a first embodiment of the present application. Notably, the exemplary structure illustrated in FIG. 1A includes a first bonding dielectric layer 14 located on a wafer 10, wherein the first bonding dielectric layer 14 contains a plurality of patterned structures 12 which are entirely embedded in the first bonding dielectric layer 14 and formed on a surface (i.e., a topmost surface) of the wafer 10. In this embodiment, the first bonding dielectric layer 14 containing the patterned structures 12 serves as a stress modulating pattern containing bonding dielectric layer.

Typically, the wafer 10 is composed of any semiconductor material having semiconductor properties. Examples of semiconductor materials that can be used in the present application in providing the wafer 10 include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments of the present application, the wafer 10 can be a bulk semiconductor substrate, i.e., a substrate that is composed entirely of at least one semiconductor material. In other embodiments of the present application, the wafer 10 can be a semiconductor-on-insulator substrate (SOI), i.e., a substrate that includes a bottom semiconductor material layer, a buried insulator layer (e.g., silicon dioxide and/or boron nitride) and a top semiconductor material layer. The wafer 10 can include also be composed of a non-semiconductor substrate such as, for example, glass. In some embodiments, the wafer 10 is a handler substrate.

The patterned structures 12 are arranged in patterns that counter wafer warpage that can occur. In some embodiments, the plurality of patterned structures 12 are arrays of continuous or discontinuous lines, arranged with uniform or non-uniform density. In some embodiments, the patterned structures 12 are present entirely across the wafer 10, or the patterned structures 12 are present in some regions on the wafer 10, but not in other regions on the wafer 10. In some embodiments, the patterned structures 12 can be arranged in an orthogonal grid pattern as is illustrated in FIG. 1C, or they can be arranged in a polar grid pattern as is illustrated in FIG. 1D. In either of the embodiments, the patterned structures 12 can be formed in some quadrants of the pattern, but not other quadrants of the pattern. The patterned structures 12 can have a height, i.e., vertical thickness, from hundreds of nm to micrometers range, and a lateral width from hundreds of nm to micrometers range. The patterned structure 12 pitch can be from hundreds of nm to micrometers range. In the present application, the pitch is measured from one point (e.g., a central point) of a first patterned structure to the exact point (e.g., a central point) of a nearest neighboring patterned structure.

In some embodiments, the patterned structures 12 are metal structures. Metal structures are composed of at least one metal such as, for example, Cu, Co, W, Al, Pt, Pd, Ag, Rh, or Ru. The term “at least one metal” includes an unalloyed metal or metal alloys (such as, for example, a Cu—Al alloy). The metal structures can be a single layered metal structure or a multi-layered metal structure including various metal layers that are stacked one atop the other.

In some embodiments, the patterned structures 12 are dielectric structures. Dielectric structures are composed of at least one dielectric material such as, for example, silicon dioxide, silicon nitride or silicon oxynitride. The dielectric structures can be a single layered dielectric material structure or a multi-layered dielectric material structure including various dielectric material layers that are stacked one atop the other.

In yet other embodiments, the patterned structures 12 can include a metal layer and a dielectric material layer stacked one atop the other and in any stacking order.

The first bonding dielectric material layer 14 is composed any bonding dielectric material such as, for example, a dielectric oxide, a dielectric nitride or a combination thereof. Note that the first bonding dielectric material layer 14 is compositionally different from the material that provides the plurality of patterned structures 12. Examples of bonding dielectric materials that can be used as the first bonding dielectric material layer 14 include, but are not limited to, SiO₂, SiN and/or SiCN. The first bonding dielectric material layer 14 can be a single layered dielectric material structure or a multi-layered dielectric material structure including various dielectric material layers that are stacked one atop the other. The first bonding dielectric material layer 14 has a vertical thickness that is greater than the height, i.e., vertical thickness of the plurality of patterned structures 12.

The exemplary structure shown in FIG. 1A can be formed by first forming the plurality of patterned structures 12 on the surface of wafer 10. The plurality of patterned structures 12 can be formed by first depositing a blanket layer or blanket layers of a metal and/or a dielectric material as defined above for the patterned structures 12 on the wafer 10. This first depositing can include, but is not limited to, chemical vapor deposition (CVD), plasma enhanced chemical vapor deposition (PECVD), physical vapor deposition (PVD), atomic layer deposition (ALD) sputtering, or plating. After forming the blanket layer or the blanket layers, a patterning process such as, for example, lithography and etching can be used to pattern the blanket layer or the blanket layers into the patterned structures. Alternatively, the patterned structures 12 can be formed utilizing a sidewall image transfer (SIT) process. After forming the patterned structures 12, the first bonding dielectric layer 14 is formed by second depositing a dielectric oxide and/or dielectric nitride as mentioned above for the first bonding dielectric layer 14. The second depositing can include, but is not limited to, CVD, PECVD, PVD or ALD.

Referring now to FIG. 1B, there is illustrated an exemplary structure that can be employed in accordance with a second embodiment of the present application. The exemplary structure of this second embodiment includes first bonding dielectric layer 14 located on wafer 10, wherein the first bonding dielectric layer 14 contains a plurality of patterned structures 12 which are partially embedded in both the first bonding dielectric layer 12 and the wafer 10. In this embodiment, the first bonding dielectric layer 14 containing the patterned structures 12 serves as a stress modulating pattern containing bonding dielectric layer. The wafer 10, the patterned structures 12 and the first bonding dielectric material layer 14 include materials as mentioned above for the first embodiment that is illustrated in FIG. 1A. The patterned structures 12 can have a height, lateral width and pitch as mentioned above in the first embodiment. The patterned structures 12 of this second embodiment can be arranged in a manner (see, for example, FIGS. 1C and 1D) as mentioned above for the patterned structures 12 of the first embodiment.

The exemplary structure shown in FIG. 1B can be formed by first forming a plurality of trenches in the wafer 10. The plurality of trenches can be formed by lithography and etching. The plurality of trenches physically expose a sub-surface of the wafer 10. The term “sub-surface” is defined herein as a surface of a material that is located between a topmost surface and a bottommost surface of the material. The patterned structures 12 of this second embodiment are then formed utilizing the technique mentioned above for forming the patterned structures 12 in the first embodiment of the present application. In this embodiment, the patterned structures 12 fill each of the trenches and extend vertically outward from the trenches. The first bonding dielectric layer 14 of this second embodiment is then formed utilizing one of the deposition processes mentioned above in forming the first bonding dielectric layer 14 of the first embodiment of the present application.

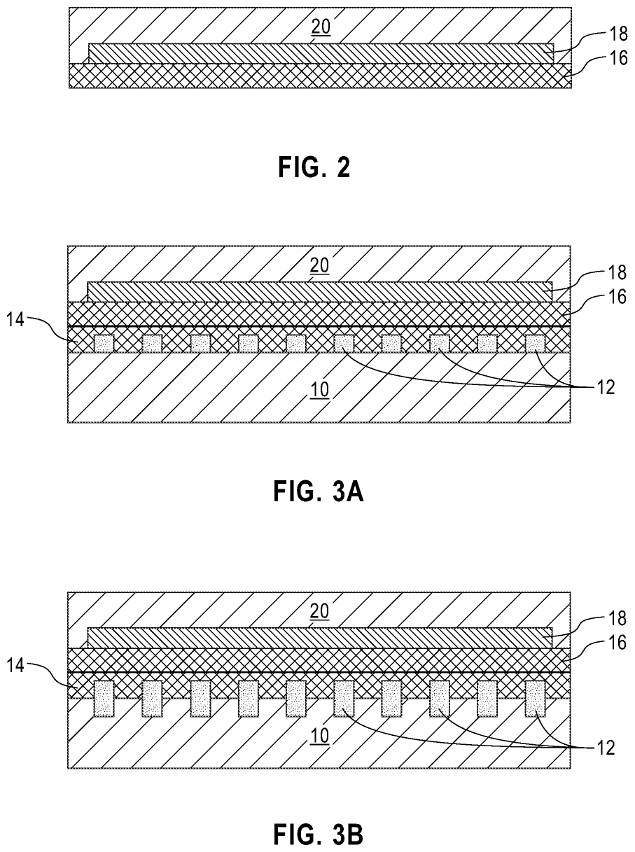

Referring now to FIG. 2, there is illustrated a device containing structure that can be employed in the present application. The device containing structure shown in FIG. 2 includes a device-containing region 18 located on a second bonding dielectric layer 16, and a device wafer 20 located on the device-containing region 18 and physically exposed portions of the second bonding dielectric layer 16 not including the device-containing region 18. The device containing structure shown in FIG. 2 is flipped such that the device wafer 20 is positioned above the second bonding layer 16.

The second bonding dielectric layer 16 includes one of the dielectric materials mentioned above for the first bonding dielectric layer 14. The dielectric material that provides the second bonding dielectric layer 16 can be compositionally the same as, or compositionally different from, the dielectric material that provides the first bonding dielectric layer 14. Typically, the dielectric materials that provide the first and second bonding dielectric layers 14, 16 are compositionally the same such that no material interface exists between these two layers. In one example, the first and second bonding dielectric layers 14, 16 are both composed of SiO₂. The second bonding dielectric layer 16 can have a thickness from tens of nm to micrometer range; although other thicknesses are contemplated and can be used as the thickness of the second bonding dielectric layer 16.

The device-containing region 18 includes at least one semiconductor device that is formed on, or within, a semiconductor material layer (this semiconductor material layer can be an upper portion of the device wafer 20). The at least one semiconductor device can include, but is not limited to, a transistor, a resistor, a capacitor, a diode, middle-of-the-line (MOL) contact structures, back-end-of-the-line (BEOL) wiring structures or any combination thereof. In one example, the at least one semiconductor device is a transistor that includes a gate structure and a source/drain region located on each side of the gate structure. The transistor can be a planar transistor, a fin-type field effect transistor (finFET), a nanosheet transistor, and/or a semiconductor nanowire transistor.

The device wafer 20 includes one of the semiconductor materials mentioned above for the wafer 10. The device wafer 20 can be a bulk semiconductor substrate or an SOI substrate as defined above.

The device containing structure shown in FIG. 2 can be formed by first forming the device-containing region 18 on the device wafer 20. The forming of the device-containing region 18 is well known to those skilled in the art and can include front-end-of-the-line (FEOL) device processing steps, MOL processing steps and BEOL processing steps. The second bonding dielectric layer 16 can be formed utilizing one of the deposition processes mentioned above for the first dielectric material layer 14 of the first embodiment of the present application.

Referring now to FIG. 3A, there is illustrated an exemplary structure that is formed after bonding the first bonding dielectric layer 14 of the exemplary structure shown in FIG. 1A to the second bonding dielectric layer 16 of the device containing structure shown in FIG. 2. FIG. 3B shows an exemplary structure that is formed after bonding the first bonding dielectric layer 14 of the exemplary structure shown in FIG. 1B to the second bonding dielectric layer 16 of the device containing structure shown in FIG. 2. In both FIGS. 3A-3B, the dotted line represents a bonding interface that is formed between the first bonding dielectric layer 14 and the second bonding dielectric layer 16. The bonding interface denotes a region in which chemical bonds are formed between the first and second bonding dielectric layers 14, 16.

In the present application, bonding can be achieved by first bringing the first bonding dielectric layer 14 in intimate physical contact with the second bonding dielectric layer 16. In some embodiments, an external force such as, for example, a bonding head can be used to maintain this intimate physical contact between the first bonding dielectric layer 14 and the second bonding dielectric layer 16. With intimate physical contact being established between the first bonding dielectric layer 14 and the second bonding dielectric layer 16, the structure can be heated to a temperature that forms a permanent bonding interface between these two bonding dielectric layers. This bonding temperature can be a temperature from 200° C. to 400° C. Bonding can be performed in various inert ambients (e.g., He, Ne, and/or Ar) or in a vacuum. Bonding can be performed for various time periods. In one example, bonding occurs over a timer period of from 5 minutes to 30 minutes.

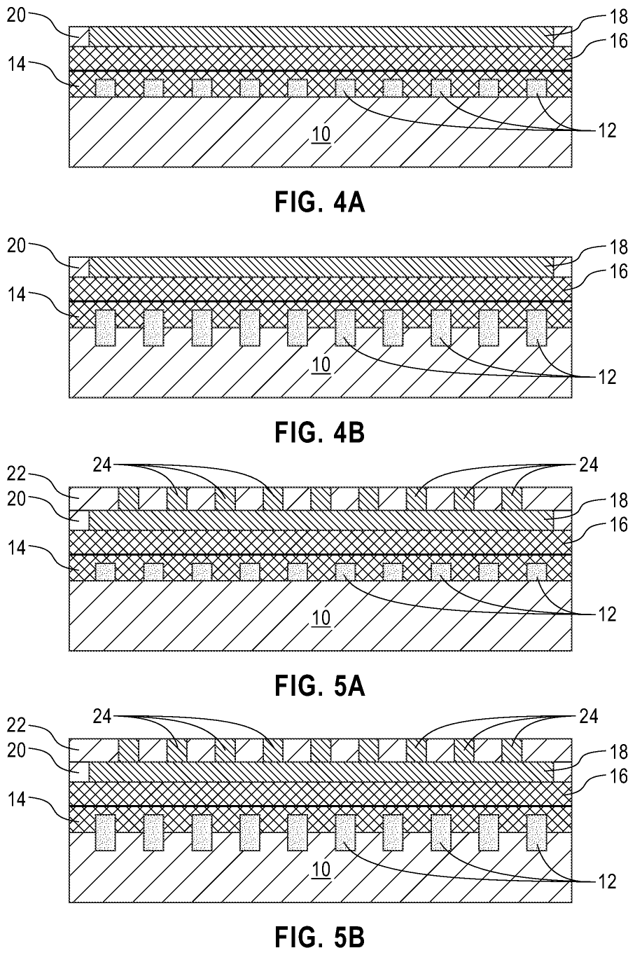

Notably, FIGS. 3A and 3B illustrates semiconductor structures in accordance with the present application. Each semiconductor structure includes first bonding dielectric layer 14 located on a surface of wafer 10, second bonding dielectric layer 16 located on the first bonding dielectric layer 14, device-containing region 18 located on the second bonding dielectric layer 16, and device wafer 20 located on the device-containing region 18. In accordance with the embodiments illustrated in FIGS. 3A-3B, the first bonding dielectric layer 14 is a stress modulating pattern containing bonding dielectric layer including the plurality of patterned structures 12. Warpage modulation can be achieved using such a stress modulating pattern containing bonding dielectric layer. That is, warpage has been modulated in the structures shown in FIGS. 3A-3B which allows for backside process of each of the structures without the need to worry about alignment/overlay issues. FIGS. 4A-6B, illustrates one possible backside process that can be performed on the exemplary structures shown in FIGS. 3A-3B.

Notably, FIGS. 4A and 4B illustrates the exemplary structures shown in FIGS. 3A and 3B, respectively, after thinning the device wafer 20 to physically expose the device-containing region 18. Thinning can be performed utilizing an etch back process or a planarization process such as, for example, wafer grinding, chemical mechanical polishing (CMP), and reactive ion etching (RIE). At this point of the present application, the thinned device wafer 20 has a topmost surface that is coplanar with a topmost surface of the device-containing region 18.

Referring now to FIGS. 5A-5B, there are illustrated the exemplary structures shown in FIGS. 4A-4B, respectively, after backside processing, the backside processing including forming a backside interlayer dielectric material layer 22 having wiring and/or contact structures 24 embedded therein. The backside interlayer dielectric material layer 22 having the wiring and/or contact structures 24 formed therein can be one or more level of a backside back-end-of-the-line (BEOL) interconnect structure. The backside interlayer dielectric material layer 22 can be composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The backside interlayer dielectric material layer 22 formed utilizing a deposition process such as, for example, CVD, PECVD, ALD or spin-on coating.

Wiring and/or contact structures 24 include at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The wiring and/or contact structures 24 can also include one or more liners (not shown). In one or more embodiments, the liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a liner is present, the liner (not shown) can include a silicide liner, such as Ti, Ni, NiPt, etc., and a diffusion barrier material, as defined above. The wiring and/or contact structures 24 are formed utilizing a metallization process that is well known to those skilled in the art.

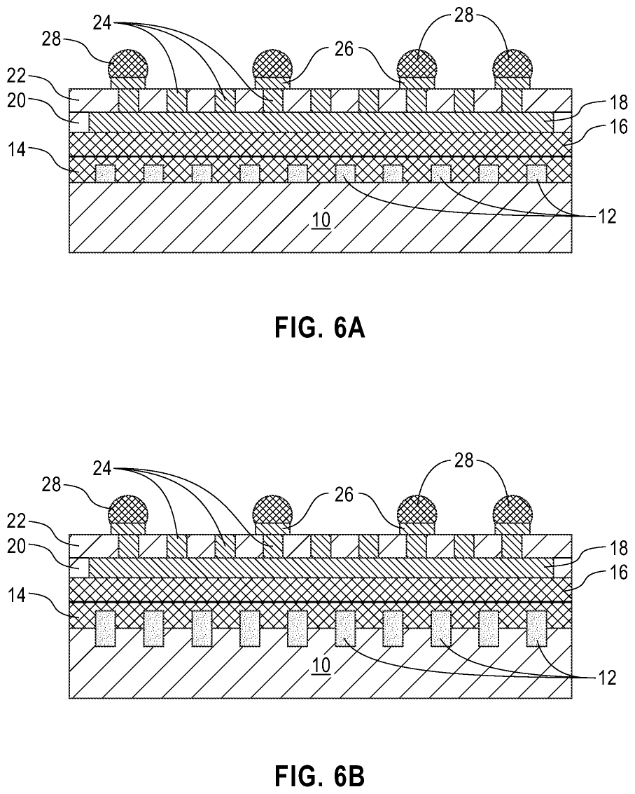

Referring now to FIGS. 6A-6B, there are illustrated the exemplary structures shown in FIGS. 5A-5B post solder bump formation. Notably, the exemplary structures shown in FIGS. 6A-6B include a solder pad 26 located on a surface of each of the wiring and/or contact structures 24, and a solder bump 28 located on each solder pad 26. In some embodiments, not all the wiring and/or contact structures 24 contain solder pads 26 and solder bumps 28. Solder pads 26 are typically composed of a metal such as, for example, Cu, Au, Ni or a mixture including alloys thereof. The solder pads 26 can be formed by lithography and electroplating. The patterning process can include lithography and etching. The solder bumps (or balls) 28 can be composed of any well known solder material including, for example, Sn, Ag, Au, Bi or a mixture including alloy thereof. The solder bumps 28 can be formed utilizing techniques that are well known to those skilled in the art. Following solder bump formation, the wafer 10 can be diced into individual die that are then bonded to a substrate as part of a microelectronic assembly. During the dicing process, the device wafer 20 is also diced into individual device die.

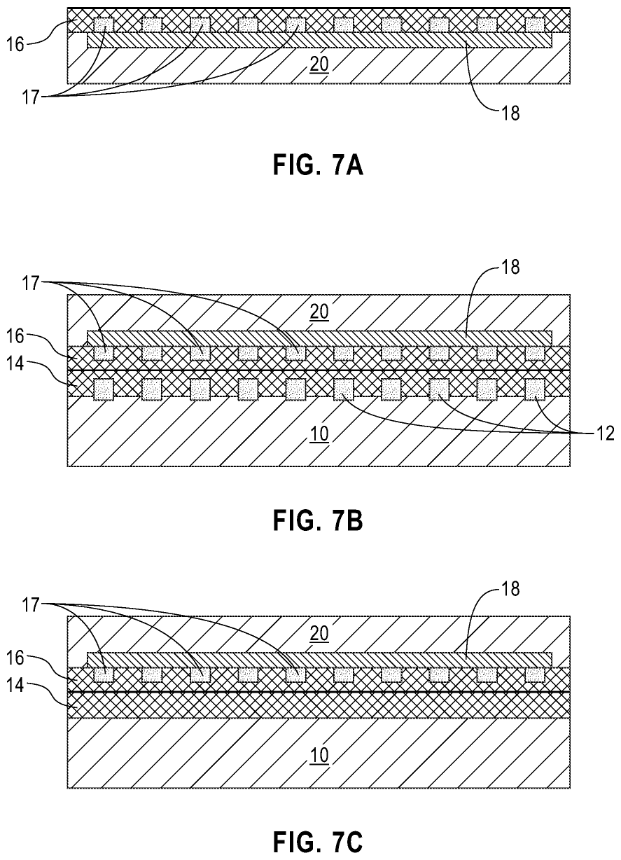

Reference is now made to FIG. 7A, which illustrates an exemplary structure that can be employed in accordance with a third embodiment of the present application. In the third embodiment, second bonding dielectric layer 16 is located on a device-containing region 18 that is located on a device wafer 20. In this third embodiment, the second bonding dielectric layer 16 contains a plurality of patterned structures 17 which are entirely embedded in the second bonding dielectric layer 16 and formed on the device-containing region 18. In this third embodiment, the second bonding dielectric layer 16 containing the plurality of patterned structures 17 serves as a stress modulating pattern containing bonding dielectric layer. Each of the second bonding dielectric material layer 16, the device-containing region 18 and the device wafer 20 include materials as mentioned above for providing the structure shown in FIG. 2 of the present application. In this third embodiment, the plurality of patterned structures 17 are the same as the patterned structures 12 shown in the first and second embodiments above. Although not shown, the present application also works when the plurality of patterned structures 17 are partially embedded in both the second bonding dielectric layer 16 and the device-containing region 18.

The exemplary structure shown in FIG. 7A can be formed utilizing the processing steps mentioned above for forming the exemplary structure shown in FIG. 2 with the modification that the plurality of patterned structures 17 are formed on the device-containing region 18 prior to forming the second bonding dielectric layer 16. The plurality of patterned structures 17 are formed using the same technique as that mentioned above for forming the plurality of patterned structures 12 in the first embodiment of the present application. The plurality of patterned structures 17 can be arranged in a manner as mentioned above for the plurality of patterned structures 12.

Referring now to FIG. 7B, there is illustrated the exemplary structure shown in FIG. 7A after bonding the second bonding dielectric layer to the first bonding dielectric layer 14 shown in FIG. 1A. In this example, the first bonding dielectric layer 14 includes a plurality of patterned structures 12 embedded therein. Here, each of the first bonding dielectric layer 14 and the second bonding dielectric layer 16 serves as a stress modulating pattern containing bonding dielectric layer. Bonding can be performed as described above. Warpage modulation is achieved in the structure due to the presence of the two stress modulating pattern containing bonding dielectric layers. Backside processing including the one depicted in FIGS. 4A-6B can be performed on the structure shown in FIG. 7B. It is noted that in this embodiment, the structure shown in FIG. 1B can be used in place of the structure shown in FIG. 1A.

Referring now to FIG. 7C, there is illustrated the exemplary structure shown in FIG. 7A after bonding the second bonding dielectric layer 16 to a first bonding dielectric layer 14 that is located on wafer 10; in this example, the first bonding dielectric layer 16 does not include a plurality of patterned structures 12 embedded therein. Here, only the second bonding dielectric layer 16 serves as a stress modulating pattern containing bonding dielectric layer. Bonding can be performed as described above. Warpage modulation is achieved in the structure due to the presence of the stress modulating pattern containing bonding dielectric layer. Backside processing including the one depicted in FIGS. 4A-6B can be performed on the structure shown in FIG. 7C.

It is noted that in any of FIGS. 7A-7C, the plurality of patterned structure can extend into the device-containing region 18.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first bonding dielectric layer located on a surface of a wafer;
a second bonding dielectric layer located on the first bonding dielectric layer;
a device-containing region located on the second bonding dielectric layer; and
a device wafer located on the device-containing region, wherein at least one of the first bonding dielectric layer or the second bonding dielectric layer is a stress modulating pattern containing bonding dielectric layer comprising a plurality of patterned structures.

2. The semiconductor structure of claim 1, wherein only the first bonding dielectric layer is the stress modulating pattern containing bonding dielectric layer.

3. The semiconductor structure of claim 2, wherein the plurality of patterned structures are entirely embedded in the first bonding dielectric layer, and are present on a topmost surface of the wafer.

4. The semiconductor structure of claim 2, wherein the plurality of patterned structures are embedded in both the first bonding dielectric layer and the wafer.

5. The semiconductor structure of claim 1, wherein only the second bonding dielectric layer is the stress modulating pattern containing bonding dielectric layer.

6. The semiconductor structure of claim 5, wherein the plurality of patterned structures are embedded in at least the second bonding dielectric layer, and are contact with the device-containing region.

7. The semiconductor structure of claim 1, wherein both the first bonding dielectric layer and the second bonding dielectric layer are stress modulating pattern containing bonding dielectric layers.

8. The semiconductor structure of claim 7, wherein the plurality of patterned structures that are present in the first bonding dielectric layer are entirely embedded in the first bonding dielectric layer, and are present on a topmost surface of the wafer.

9. The semiconductor structure of claim 7, wherein the plurality of patterned structures that are present in the first bonding dielectric layer are embedded in both the first bonding dielectric layer and the wafer.

10. The semiconductor structure of claim 7, wherein the plurality of patterned structures that are present in the second bonding dielectric layer are at least partially embedded in the second bonding dielectric layer, and are in contact with the device-containing region.

11. The semiconductor structure of claim 1, wherein the plurality of patterned structures are patterned metal structures.

12. The semiconductor structure of claim 1, wherein the plurality of patterned structures are patterned dielectric structures.

13. The semiconductor structure of claim 1, wherein the plurality of patterned structures are arranged in an orthogonal grid pattern.

14. The semiconductor structure of claim 1, wherein the plurality of patterned structures are arranged in a polar grid pattern.

15. The semiconductor structure of claim 1, wherein the plurality of patterned structures are arrays of continuous or discontinuous lines, arranged with uniform or non-uniform density.

16. The semiconductor structure of claim 15, further comprising:
a backside interlayer dielectric material layer located on device-containing region and the device wafer, wherein wiring and/or contact structures are embedded in the backside interlayer dielectric material layer.

17. The semiconductor structure of claim 16, further comprising:
a solder pad located on a surface of the wiring and/or contact structures; and
a solder bump located on each solder pad.

18. The semiconductor structure of claim 1, wherein the device-containing region comprises at least one semiconductor device.

19. The semiconductor structure of claim 1, wherein a bonding interface exists between the first bonding dielectric layer and the second bonding dielectric layer.

20. A microelectronic assembly comprising:
a first bonding dielectric layer located on a surface of a die;
a second bonding dielectric layer located on the first bonding dielectric layer;
a device-containing region located on the second bonding dielectric layer; and
a device die located on the device-containing region, wherein at least one of the first bonding dielectric layer or the second bonding dielectric layer is a stress modulating pattern containing bonding dielectric layer comprising a plurality of patterned structures.
